(19) United States
(12) Patent Application Publication
(10) Pub. No.: US 2013/0087192 A1
(43) Pub. Date: Apr. 11, 2013

(54) PHOTOVOLTAIC DEVICE

(71) Applicants: Young-Su Kim, Yongin-si (KR); Doo-Youl Lee, Yongin-si (KR); Young-Jin Kim, Yongin-si (KR); Chan-Bin Mo, Yongin-si (KR); Young-Sang Park, Yongin-si (KR)

(72) Inventors: Young-Su Kim, Yongin-si (KR); Doo-Youl Lee, Yongin-si (KR); Young-Jin Kim, Yongin-si (KR); Chan-Bin Mo, Yongin-si (KR); Young-Sang Park, Yongin-si (KR)

(21) Appl. No.: 13/445,851

(22) Filed: Apr. 12, 2012

Related U.S. Application Data
(60) Provisional application No. 61/544,111, filed on Oct. 6, 2011.

(51) Int. Cl. H01L 31/0224; H01L 31/18

(52) U.S. Cl. 136/256; 438/68; 257/E31.124

(57) ABSTRACT

A photovoltaic device, and a method of fabricating the same are provided. Here, a base portion and an emitter portion are formed on a surface of a semiconductor substrate. An insulation layer is formed on the base portion and the emitter portion. The insulation layer has a plurality of vias to partially expose the base portion and the emitter portion. A first electrode is formed to contact a region of the emitter portion through at least one of the vias, and a second electrode is formed to contact a region of the base portion through at least another one of the vias. Then, a dicing line is set at a bus electrode portion of the second electrode, and the semiconductor substrate is split into at least two photovoltaic devices at the base portion along the dicing line.

### CROSS-REFERENCE TO RELATED APPLICATION

This application claims the benefit of and priority to U.S. Provisional Application No. 61/544,111, filed on Oct. 6, 2011, in the United States Patent and Trademark Office, the disclosure of which is incorporated herein in its entirety by reference.

### BACKGROUND

1. Field

One or more embodiments of the present invention relate to photovoltaic devices.

2. Description of Related Art

To fabricate a photovoltaic device, a p-n junction is formed by doping an n-type impurity (or a p-type impurity) into a p-type substrate (or an n-type substrate), and thus an emitter is formed. Electron-hole pairs formed via reception of light are separated. Here, electrons are collected by an electrode in an n-type region, whereas holes are collected by an electrode in a p-type region. Therefore, power is generated.

A photovoltaic device may have a structure in which electrodes are respectively arranged on a front surface as a light-receiving surface and on a rear surface. Here, if an electrode is arranged on the front surface, an area for receiving light is reduced by as much as an area of the electrode. To resolve the area reduction problem, a back contact structure in which electrodes are arranged only on a rear surface of a substrate is employed.

### SUMMARY

Aspects of embodiments of the present invention are directed toward photovoltaic devices, and methods of fabricating the same.

An aspect of an embodiment of the present invention is directed toward a method of fabricating a photovoltaic device in which a dicing line is set at a base portion of a semiconductor substrate (e.g., at a base portion of a semiconductor wafer), and the semiconductor substrate is diced along the dicing line.

An aspect of an embodiment of the present invention is directed toward a photovoltaic device having a first electrode contacting a region of an emitter portion of the photovoltaic device and a second electrode contacting a region of the base portion of the photovoltaic device. Here, the second electrode is a diced electrode, and the photovoltaic device has only two trimmed corner portions at its emitter portion.

An embodiment of the present invention provides a method of fabricating a photovoltaic device. The method includes: forming a semiconductor substrate to have a first surface and a second surface, the second surface facing oppositely away from the first surface; forming a base portion and an emitter portion at the first surface; forming an insulation layer on the base portion and the emitter portion; forming a plurality of vias in the insulating layer to partially expose the base portion and the emitter portion; forming a first electrode to contact a region of the emitter portion through at least one of the vias; forming a second electrode to contact a region of the base portion through at least another one of the vias; setting a dicing line at the base portion; and dicing the semiconductor substrate along the dicing line.

In one embodiment, the setting of the dicing line includes setting the dicing line at the base portion and away from the emitter portion, and the dicing of the semiconductor substrate includes dicing the semiconductor substrate at a region of the semiconductor substrate away from the emitter portion.

In one embodiment, the forming of the first electrode includes forming the first electrode to include a first bus bar and a plurality of first finger electrodes extending from the first bus bar, and the forming of the second electrode includes forming the second electrode to include a second bus bar arranged to extend across the center of the first surface and a plurality of second finger electrodes extending from the second bus bar and interdigitated with the first finger electrodes. In addition, the setting of the dicing line at the base portion may include forming an opening to extend across the center of the second bus bar to become the dicing line.

In one embodiment, the forming of the semiconductor substrate includes forming the semiconductor substrate from a single semiconductor wafer by trimming at least two corner portions of the semiconductor wafer. Here, a plurality of photovoltaic devices may be formed from the single semiconductor wafer. In addition, the forming of the first electrode may include forming the first electrode in each of the photovoltaic devices to include a first bus bar and a plurality of first finger electrodes extending from the first bus bar in each of the photovoltaic devices, and the forming of the second electrode may include forming the second electrode in each of the photovoltaic devices to include a second bus bar and a plurality of second finger electrodes extending from the second bus bar.

In one embodiment, the method of claim further includes forming at least one of a passivation layer or an anti-reflection layer at the second surface of the semiconductor substrate.

In one embodiment, the method of claim further includes texturing the second surface of the semiconductor substrate.

In one embodiment, each of the base portion and the emitter portion is formed to have a stripe shape.

In one embodiment, each of the base portion and the emitter portion is formed as a plurality of discrete regions. Here, each of the discrete regions may have a dot, elliptical, circular, or polygonal shape.

In one embodiment, the second surface is formed as a front surface configured to face a light source, and the first surface is formed as a rear surface configured to face away from the light source.

An embodiment of the present invention provides a photovoltaic device. The photovoltaic device includes: a semiconductor substrate having a first surface and a second surface, the second surface facing oppositely away from the first surface; a base portion and an emitter portion at the first surface; an insulation layer on the base portion and the emitter portion, the insulation layer having a plurality of vias; a first electrode contacting a region of the emitter portion through at least one of the vias; and a second electrode contacting a region of the base portion through at least another one of the vias. Here, the second electrode is a diced electrode, and the semiconductor substrate has only two trimmed corner portions at the emitter portion.

In one embodiment, the semiconductor substrate is formed from a semiconductor wafer and is about half (½) the size of the semiconductor wafer. Here, a portion of the second electrode may extend across the center of the semiconductor wafer.

In one embodiment, the first electrode includes a first bus bar extending along a first edge of the semiconductor substrate between the two trimmed corner portions, and a plurality of first finger electrodes extending from the first bus bar; and the second electrode includes a second bus bar extending along a second edge opposite to the first edge, and a plurality of second finger electrodes extending from the second bus bar and interdigitated with the first finger electrodes.

In one embodiment, the photovoltaic device further includes at least one of a passivation layer or an anti-reflection layer at the second surface of the semiconductor substrate.

In one embodiment, each of the base portion and the emitter portion is formed to have a stripe shape.

In one embodiment, each of the base portion and the emitter portion is formed as a plurality of discrete regions.

In one embodiment, the insulation layer includes a first layer and a second layer differing in material from the first layer.

### BRIEF DESCRIPTION OF THE DRAWINGS

FIG. 1A is a schematic perspective view of a photovoltaic device according to an embodiment of the present invention;

FIG. 1B is a sectional view taken along a line IB-IB of FIG. 1A;

FIG. 2A is a rear view of a photovoltaic device according to an embodiment of the present invention, showing first and second metal electrodes, an emitter layer, and a base layer;

FIG. 2B is a rear view of a photovoltaic device according to another embodiment of the present invention, showing first and second metal electrodes, an emitter layer, and a base layer;

FIG. 3A is a perspective view of a semiconductor substrate during a process fabricating a photovoltaic device according to an embodiment of the present invention;

FIG. 3B is a perspective view of a semiconductor substrate according to a modification of the embodiment shown in FIG. 3A;

FIG. 4 is a perspective view of a state in which a passivation layer and an anti-reflection layer are formed during a process of fabricating a photovoltaic device according to an embodiment of the present invention;

FIG. 5A is a perspective view of a state in which a passivation layer and an anti-reflection layer are formed during a process of fabricating a photovoltaic device according to an embodiment of the present invention;

FIG. 5B is a sectional view taken along a line VB-VB of FIG. 5A;

FIG. 6A is a perspective view of a state in which an insulation layer is formed during a process of fabricating a photovoltaic device according to an embodiment of the present invention;

FIG. 6B is a sectional view taken along a line VIB-VIB of FIG. 6A;

FIG. 7A is a perspective view of a state in which first and second metal electrodes are formed during a process of fabricating a photovoltaic device according to an embodiment of the present invention;

FIG. 7B is a sectional view taken along a line VIIB-VIIB of FIG. 7A;

FIG. 7C is a rear view of FIG. 7A;

FIG. 8A is a perspective view of a state in which a semiconductor substrate is diced along a dicing line C-C of FIG. 7A during a process of fabricating a photovoltaic device according to an embodiment of the present invention;

FIG. 8B is a rear view of FIG. 8A;

FIGS. 9A and 9B show results of measuring quantum efficiencies (QEs) of comparable back contact photovoltaic devices using a laser beam induced current (LBIC) method;

FIG. 10 shows an embodiment of electrically interconnecting photovoltaic devices according to an embodiment of the present invention;

FIG. 11 shows an embodiment of electrically interconnecting photovoltaic devices according to another embodiment of the present invention; and

FIG. 12 shows an embodiment of electrically interconnecting photovoltaic devices according to another embodiment of the present invention.

### DETAILED DESCRIPTION

The invention now will be described more fully hereinafter with reference to the accompanying drawings, in which illustrative embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes,” “comprises”, “including,” and/or “comprising,” when used in this specification, specify the presence of stated features, integers, steps, operations, elements, and/or components, but do not preclude the presence or addition of one or more other features, integers, steps, operations, elements, components, and/or groups thereof. While such terms as “first,” “second,” etc., may be used to describe various components, such components should not be limited to the above terms. That is, the above terms may be used only to distinguish one component from another. Like numbers refer to like elements throughout.

In the drawings, the thicknesses of layers and regions are exaggerated for clarity. It will be understood that when an element or layer is referred to as being “on” another element or layer, the element or layer can be directly on another element, or one or more intervening layers or intervening elements may be interposed therebetween. In contrast, when an element is referred to as being “directly on” another element or layer, there are no intervening elements or layers present.

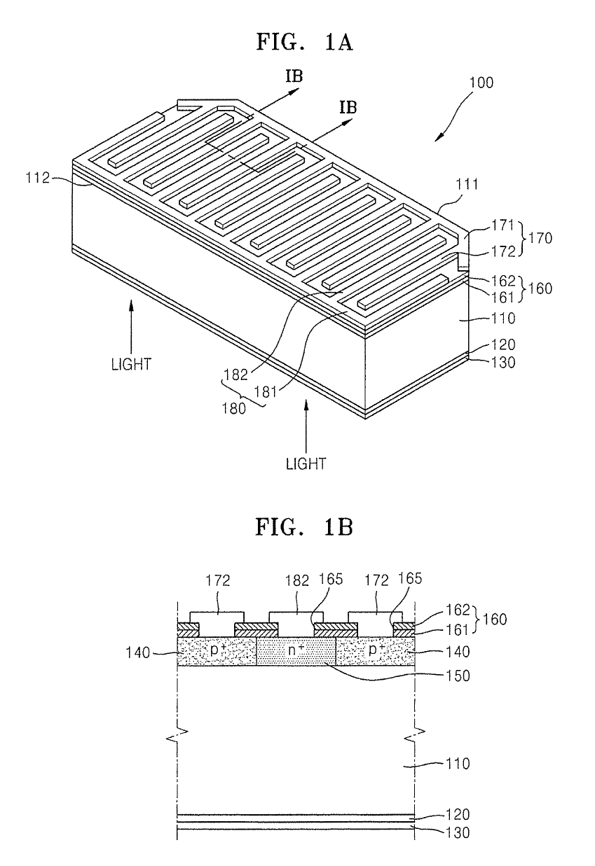

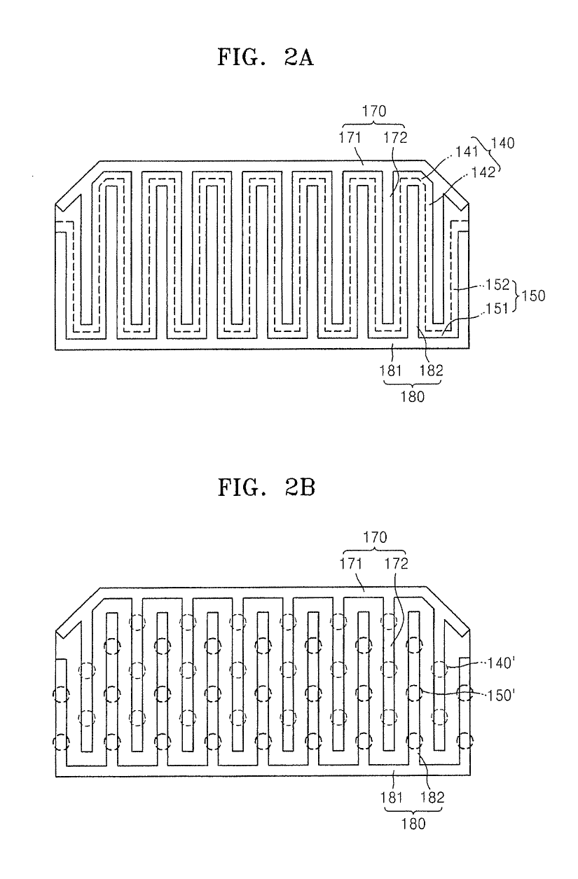

FIG. 1A is a schematic perspective view of a photovoltaic device according to an embodiment of the present invention, and FIG. 1B is a sectional view taken along a line IB-IB of FIG. 1A. FIG. 2A is a rear view of a photovoltaic device according to an embodiment of the present invention, showing first and second metal electrodes, an emitter layer, and a base layer, and FIG. 2B is a rear view of a photovoltaic device according to another embodiment of the present invention, showing first and second metal electrodes, an emitter layer, and a base layer.

For convenience of explanation, FIGS. 1A and 1B show that a rear surface of the photovoltaic device faces upward, and FIGS. 2A and 2B show regions that are doped with impurities and in which emitter and base layers (portions) are formed using dotted lines.

Referring to FIGS. 1A and 1B, a photovoltaic device 100 includes a semiconductor substrate 110, a passivation layer 120, an anti-reflection layer 130, an emitter layer (emitter portion) 140, a base layer (base portion) 150, an insulation layer 160, and first and second metal electrodes 170 and 180.

The semiconductor substrate 110 is a light-absorbing layer. Here, an edge of a first side 111 of the semiconductor substrate 110 is trimmed, and an edge of a second side 112 of the semiconductor substrate is not trimmed. Generally, four edges of a semiconductor substrate are trimmed. However, according to an embodiment of the present invention, the semiconductor substrate 110 corresponds to half of a general semiconductor substrate, where only two of four edges, that is, only edges at two opposite ends of the first side 111, are trimmed. A size of the semiconductor substrate 110 may be half of that of a 5″ or 6″ wafer or larger.

The semiconductor substrate 110 may include a monocrystalline silicon substrate or a polycrystalline silicon substrate. The semiconductor substrate 110 may be a monocrystalline silicon substrate or a polycrystalline silicon substrate, doped with an n-type impurity. The n-type impurity may include group V elements, such as phosphor (P) and arsenic (As).

Although the semiconductor substrate 110 doped with an n-type impurity is employed in the present embodiment, the present invention is not limited thereto. For example, the semiconductor substrate 110 may be a monocrystalline silicon substrate or a polycrystalline silicon substrate, doped with a p-type impurity. The p-type impurity may include group III elements, such as boron (B), aluminum (Al), or gallium (Ga).

Although not shown, the semiconductor substrate 110 may include a textured structure. The textured structure may reduce reflection of incident light, increase a length of propagation of light within the semiconductor substrate 110, and increase an amount of absorbed light by using internal reflection from a rear surface of the semiconductor substrate 110. Therefore, a short circuit current of the photovoltaic device 100 may be increased.

The passivation layer 120 may be formed on a front surface of the semiconductor substrate 110. The passivation layer 120 may contain amorphous silicon (a-Si) doped with an impurity or may contain silicon nitride (SiNₓ). In a case where the passivation layer 120 contains a-Si doped with an impurity, the passivation layer 120 may be doped with an impurity having the same conductivity as the impurity of the semiconductor substrate 110 at a concentration higher than that of the impurity of the semiconductor substrate 110.

The passivation layer 120 may improve efficiency of carrier collection by blocking or preventing surface recombination of carriers generated in the semiconductor substrate 110. For example, since the passivation layer 120 prevents carriers from moving toward the front surface of the semiconductor substrate 110, the passivation layer 120 may prevent carriers and holes from being recombined and dissipated near the front surface of the semiconductor substrate 110.

The anti-reflection layer 130 is formed on the front surface of the semiconductor substrate 110 and may improve efficiency of the photovoltaic device 100 by preventing light absorption loss of the photovoltaic device 100 due to light reflection during incidence of sunlight. The anti-reflection layer 130 may contain a transparent material. For example, the anti-reflection layer 130 may contain silicon oxide (SiOₓ), silicon nitride (SiNₓ), or silicon oxynitride (SiOₓN_{y}). Alternatively, the anti-reflection layer 130 may contain titanium oxide (TiOₓ), zinc oxide (ZnO), or zinc sulfide (ZnO). The anti-reflection layer 130 may be formed by stacking a single layer or a plurality of layers having different refraction indexes.

Although the passivation layer 120 and the anti-reflection layer 130 are represented as individual layers in the present illustrated embodiment, the present invention is not limited thereto. For example, a silicon nitride (SiNₓ) layer may be formed to function as both the passivation layer 120 and the anti-reflection layer 130.

The emitter layer 140 is formed on the rear surface of the semiconductor substrate 110 and forms a p-n junction with the semiconductor substrate 110. In a case where the semiconductor substrate 110 is doped with an n-type impurity, the emitter layer 140 contains a p-type impurity. In a case where the semiconductor substrate 110 is doped with a p-type impurity, the emitter layer 140 contains an n-type impurity.

Referring to FIG. 2A, the emitter layer 140 is formed by doping a p-type impurity (or an n-type impurity) to the semiconductor substrate 110, and a diffusion region may be a stripe type. That is, in one embodiment, the emitter layer (the emitter portion) 140 is formed to have a stripe shape.

Alternatively, referring to FIG. 2B, a diffusion region (an emitter portion) 140′ of a p-type impurity (or an n-type impurity) may be a dot type having a circular shape or an elliptical shape. The dot-type diffusion region 140′ may also have a polygonal shape. That is, in one embodiment, the emitter portion 140′ is formed as a plurality of discrete regions. Here, in one embodiment, each of the discrete regions 140′ has a dot, elliptical, circular, or polygonal shape as represented by the dashed lines in FIG. 2B.

Referring back to FIGS. 1A, 1B and 2A, the emitter layer 140 is formed at along the first side 111 of the semiconductor substrate 110, which has two trimmed edges, and is also formed at a direction perpendicular to the first side 111. That is, in one embodiment, the emitter layer 140 includes a first emitter region 141 formed along the first side 111 and a plurality of second emitter regions 142 formed in a direction substantially perpendicular to the first emitter region 141. The second emitter regions 142 are formed apart from each other.

The base layer 150 is formed on the rear surface of the semiconductor substrate 110 and contains the same type of impurity as the semiconductor substrate 110. The base layer 150 is doped with the impurity at a concentration higher than that of the impurity of the semiconductor substrate 110 to form a back surface field (BSF), so that holes and electrons may be prevented from being recombined near the second metal electrode 180 and dissipated.

Referring to FIG. 2A, the base layer (the base portion) 150 is formed by doping an n-type impurity (or a p-type impurity) to the semiconductor substrate 110, and a diffusion region may be a stripe type. That is, in one embodiment, the base layer (the base portion) 150 is formed to have a stripe shape.

Alternatively, referring to FIG. 2B, a diffusion region 150′ of an n-type impurity (or a p-type impurity) may be a dot type having a circular shape or an elliptical shape. The dot-type diffusion region 150′ may also have a polygonal shape. That is, in one embodiment, the diffusion region (the base portion) 150′ is formed as a plurality of discrete regions. Here, in one embodiment, each of the discrete regions 150′ has a dot, elliptical, circular, or polygonal shape as represented by the dashed lines in FIG. 2B.

Referring back to FIGS. 1A, 1B, and 2A, the base layer 150 is formed at along the second side 112 of the semiconductor substrate 110, which has two untrimmed edges, and is also formed at a direction perpendicular to the second side 112. That is, in one embodiment, the base layer 150 includes a first base region 151 formed along the second side 112 and a plurality of second base regions 152 formed in a direction substantially perpendicular to the first base region 151.

The second base regions 152 are arranged between the second emitter regions 142, which are apart from each other. Therefore, the second emitter regions 142 and the second base regions 152 are formed to be interdigitated on the rear surface of the semiconductor substrate 110.

The insulation layer 160 is formed on the emitter layer 140 and the base layer 150 and below the first and second metal electrodes 170 and 180 to prevent (or protect from) a short-circuit between components having opposite conductivity types (opposite polarities). For example, the insulation layer 160 prevents an electric short-circuit between the first metal electrode 170 and the base layer 150 and prevents an electric short-circuit between the second metal electrode 180 and the emitter layer 140.

The insulation layer 160 includes vias (e.g., via holes) 165 via (through) which the first and second metal electrodes 170 and 180 may directly contact the emitter layer 140 and the base layer 150, respectively. Through the via holes 165, the first metal electrode 170 may be electrically connected to the emitter layer 140, and the second metal electrode 180 may be electrically connected to the base layer 150.

The insulation layer 160 may include a first insulation layer 161 and a second insulation layer 162. For example, the first insulation layer 161 may include silicon oxide (SiOₓ), silicon nitride (SiNₓ), or both SiOₓ and SiNₓ. The second insulation layer 162 is formed for securing (or for firmer) electric insulation after formation of the first insulation layer 161 and may contain polyimide (PI). Alternatively, the second insulation layer 162 may contain ethylenevinylacetate (EVA), polyethylene terephthalate (PET), or polycarbonate (PC).

Although the insulation layer 160 includes the first insulation layer 161 and the second insulation layer 162 in the present embodiment, the present invention is not limited thereto. The second insulation layer 162 may be formed for securing electric insulation after formation of the first insulation layer 161 and may be optional, thus the insulation layer 160 may include only the first insulation layer 161.

The first metal electrode 170 is arranged on the insulation layer 160 to correspond to the emitter layer 140 and may be electrically connected to the emitter layer 140 through the via holes 165. The first metal electrode 170 may contain silver (Ag), gold (Au), copper (Cu), aluminum (Al), or an alloy thereof. The first metal electrode 170 may include a first bus bar 171 and first finger electrodes 172 that are formed to extend from (e.g., formed to be perpendicular with respect to) the first bus bar 171.

The second metal electrode 180 is arranged on the insulation layer 160 to correspond to the base layer 150 and may be electrically connected to the base layer 150 through the via holes 165. The second metal electrode 180 may contain silver (Ag), gold (Au), copper (Cu), aluminum (Al), or an alloy thereof. The second metal electrode 180 may include a second bus bar 181 and second finger electrodes 182 that are formed to extend from (e.g., formed to be perpendicular with respect to) the second bus bar 181.

The first bus bar 171 is formed at the first side 111 of the semiconductor substrate 110, whereas the second bus bar 181 is formed at the second side 112 of the semiconductor substrate 110 to be substantially parallel to the first bus bar 171. The first finger electrodes 172 extend toward the second bus bar 181 in a direction perpendicular to the first bus bar 171, whereas the second finger electrodes 182 extend toward the first bus bar 171 in a direction perpendicular to the second bus bar 181. The first finger electrodes 182 and the second finger electrodes 182 are alternately arranged. In other words, the first and second finger electrodes 172 and 182 may be formed to be interdigitated with each other and collect carriers.

In a case of fabricating a general back contact photovoltaic device, even though a light-receiving area increases, power loss proportional to the square of a current is induced when the current is increased according to the increase of the light-receiving area, and thus gain with respect to the increase of area may not be sufficiently large. However, according to embodiments of the present invention, a photovoltaic device is formed by dicing a wafer in half, and thus a voltage may be approximately doubled and a current may be reduced. Therefore, power loss proportional to the square of a current may be reduced. For example, in one embodiment, the second electrode 180 is a diced electrode. That is, in one embodiment, the second bus bar 181 of the second electrode 180 can be formed by dicing a larger bus bar into two parts as described in more detail below.

Furthermore, since a photovoltaic device according to an embodiment the present invention is fabricated by dicing a region of the base portion, i.e., dicing the region of the base portion away from the emitter portion, power loss during fabrication of the photovoltaic device may be reduced or prevented.

Hereinafter, a method of fabricating a photovoltaic device will be described.

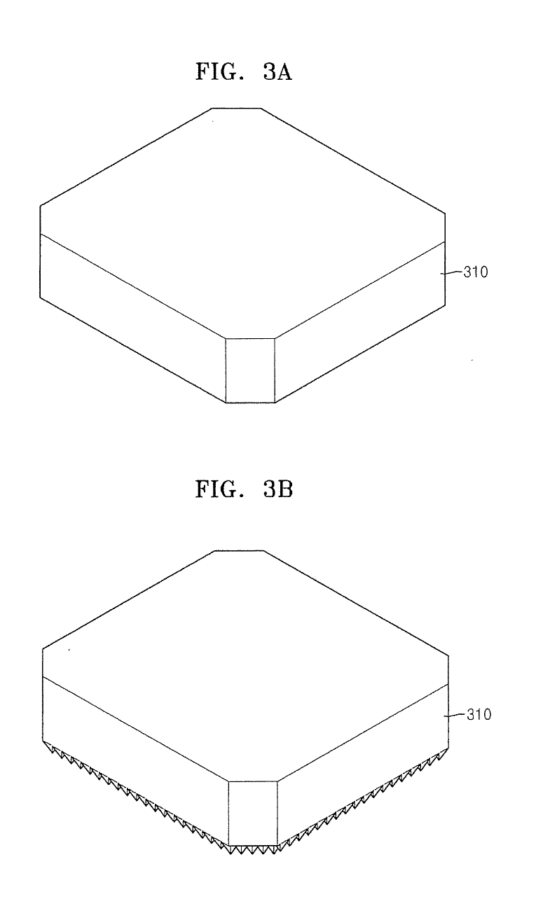

FIGS. 3A through 8B schematically show states in a method of fabricating a photovoltaic device according to an embodiment of the present invention. For convenience of explanation, FIGS. 3A through 8B show that a rear surface of the photovoltaic device faces upward.

Referring to FIG. 3A, a semiconductor substrate (e.g., a semiconductor wafer) 310 is provided. Four edges of the semiconductor substrate 310 are trimmed, and a size of the semiconductor substrate (wafer) 310 may be 5-inch, 6-inch, or larger. As an example, in one embodiment, a single semiconductor wafer that is 5-inch, 6-inch, or lager is utilized to form a plurality of photovoltaic devices. However, the present invention is not thereby limited, and other suitable type(s) or number(s) of semiconductor wafer(s) or substrate(s) may be utilized.

The semiconductor substrate 310 may include a monocrystalline silicon substrate or a polycrystalline silicon substrate. The semiconductor substrate 310 may be a monocrystalline silicon substrate or a polycrystalline silicon substrate, doped with an n-type impurity or a p-type impurity. In the present embodiment, for convenience of explanation, a case in which the semiconductor substrate 310 contains an n-type impurity will be described.

A cleaning operation using an acid solution or an alkali solution may be performed to remove physical impurities and/or chemical impurities attached to surfaces of the semiconductor substrate 310.

Referring to FIG. 3B, a semiconductor substrate 310′ according to another embodiment of the present invention may have a rough surface formed in a texturing operation. A texture structure may be formed via anisotropic wet-etching or plasma dry-etching. A passivation layer and an anti-reflection layer described below may be formed on the rough surface formed in the texturing operation.

Hereinafter, for convenience of explanation, a process of fabricating a photovoltaic device using the semiconductor substrate 310 shown in FIG. 3A will be described.

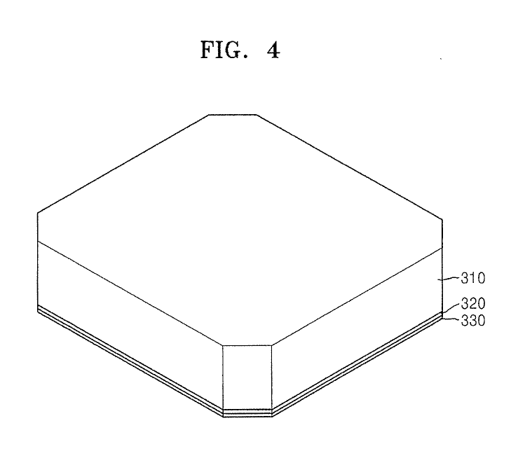

Referring to FIG. 4, a passivation layer 320 and an anti-reflection layer 330 are formed on a front surface of the semiconductor substrate 310 in the order stated. Before the passivation layer 320 is formed, the semiconductor substrate 310 may be cleaned.

The passivation layer 320 may contain a-Si doped with an impurity. For example, the passivation layer 320 may be formed on the front surface of the semiconductor substrate 310 as a high-concentration n+ layer, and the passivation layer 320 may form a front surface field (FSF) for reducing loss due to recombination of holes and electrons.

According to another embodiment of the present invention, the passivation layer 320 may contain silicon nitride (SiNₓ). The passivation layer 320 may be formed by using a plasma enhanced chemical vapor deposition (PECVD) method.

Since the passivation layer 320 is formed on a light-receiving surface of the semiconductor substrate 310, a band gap may be adjusted to reduce light absorption. For example, an additive may be added to increase a band gap to reduce light absorption, in order to pass more incident light into an interior of the semiconductor substrate 310.

The anti-reflection layer 330 may be formed of silicon oxide (SiOₓ), silicon nitride (SiNₓ), or silicon oxynitride (SiOₓN_{y}), by using a method such as CVD, sputtering, or spin coating. For example, the anti-reflection layer 330 may be formed as a single silicon oxide (SiOₓ) layer, a single silicon nitride (SiNₓ) layer, or a single silicon oxynitride (SiOₓN_{y}) layer, or as a composite layer containing silicon oxide (SiOₓ), silicon nitride (SiNₓ), and silicon oxynitride (SiOₓN_{y}).

Although the passivation layer 320 and the anti-reflection layer 330 are formed as individual layers in the present embodiment, the present invention is not limited thereto. For example, the passivation layer 320 and the anti-reflection layer 330 may be integrally formed as a single layer. In other words, a silicon nitride (SiNₓ) layer may be formed for both passivation and anti-reflection.

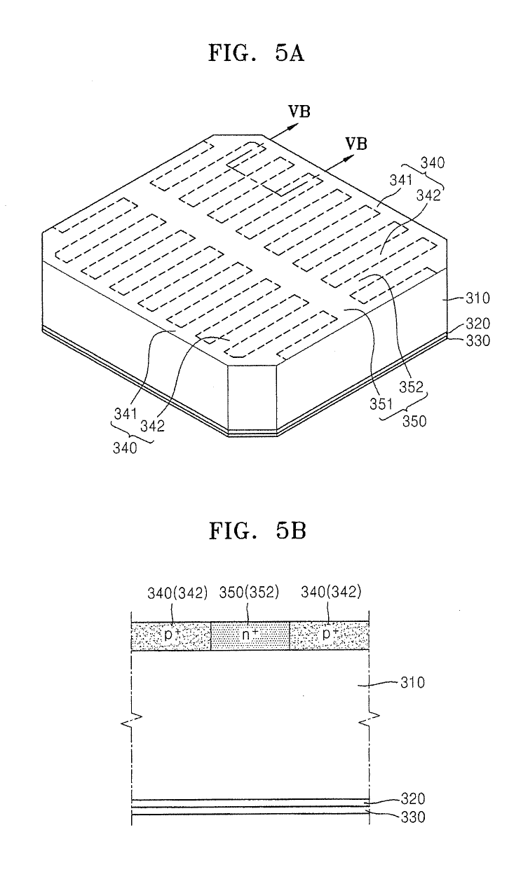

Referring to FIGS. 5A and 5B, a base layer (a base portion) 350 and an emitter layer (an emitter portion) 340 are formed on the rear surface of the semiconductor substrate 310. The base layer 350 and the emitter layer 340 may be formed by doping an impurity into the semiconductor substrate 310 in stripes.

According to an embodiment of the present invention, the base layer 350 and the emitter layer 340 may be formed by respectively doping impurities of opposite conductivity types to different regions of the rear surface of the semiconductor substrate 310. First, a first base region 351 may be formed by doping an n-type impurity into the semiconductor substrate 310 across a center region of the rear surface of the semiconductor substrate 310, and second base regions 352 may be formed by doping the n-type impurity into the semiconductor substrate 310 in a direction perpendicular to the first base region 351. Here, the second base regions 352 doped with the n-type impurity are formed to be a set or predetermined interval apart from each other.

Next, the emitter layer 340 may be formed by doping a p-type impurity into remaining regions, that is, regions other than the regions doped with the n-type impurity. Therefore, regions of the emitter layer 340 are formed at two different sides around one region of the base layer 350, and the emitter layer 340 includes a first emitter region 341 and second emitter regions 342 substantially perpendicular to the first emitter region 341, where the second emitter regions 342 are formed to be interdigitated with the second base regions 352.

According to another embodiment of the present invention, the base layer 350 is formed to cover the entire rear surface of the semiconductor substrate 310, and then the emitter layer 340 may be formed by selectively doping an impurity into portions of the base layer 350. For example, after the entire rear surface of the semiconductor substrate 310 is doped with an n-type impurity, regions of the rear surface of the semiconductor substrate 310 may be doped with a high-concentration p-type impurity to form the emitter layer (portion) 340. Here, the regions doped with the high-concentration p-type impurity are shown in FIG. 5A as the emitter layer 340.

Although the base layer 350 and the emitter layer 340 are stripe type doped regions, impurities may also be doped in discrete regions (e.g., to have dot shapes). A base doped region and an emitter doped region in a case where impurities are doped in discrete regions (e.g., to have dot shapes) are as described above with reference to FIG. 2B.

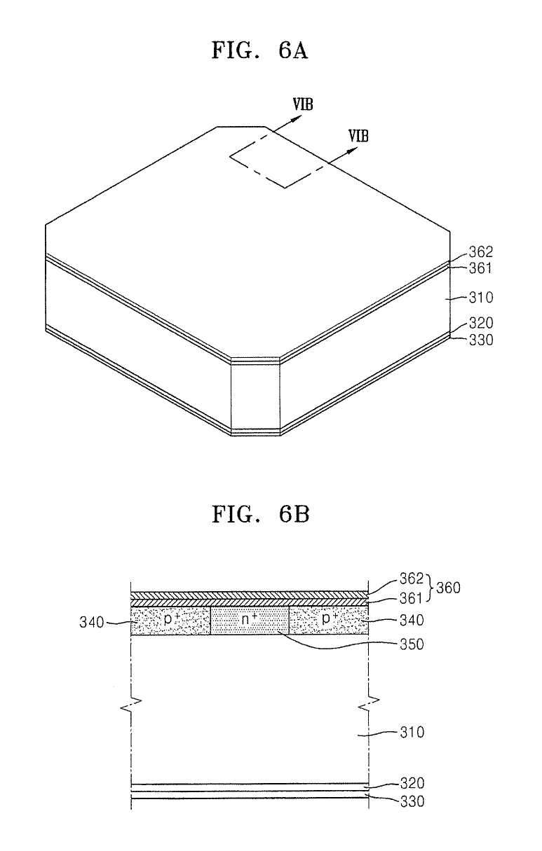

Referring to FIGS. 6A and 6B, an insulation layer 360 is formed on the base layer 350 and the emitter layer 340. The insulation layer 360 may be formed to include two layers. For example, after a first insulation layer 361 containing silicon oxide (SiOₓ) and silicon nitride (SiNₓ) is formed by using a CVD method, a second insulation layer 362 may be formed to improve electric insulation.

The second insulation layer 362 may contain polyimide (PI). Alternatively, the second insulation layer 162 may contain ethylenevinylacetate (EVA), polyethylene terephthalate (PET), or polycarbonate (PC).

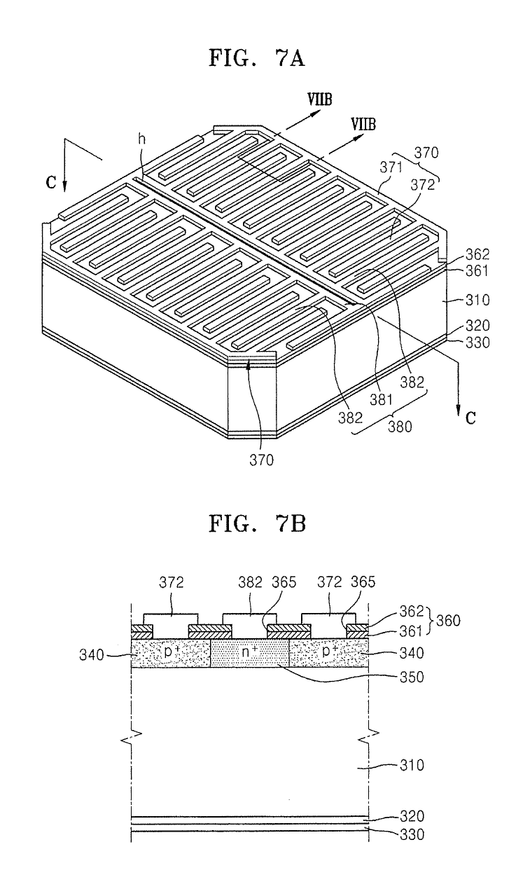

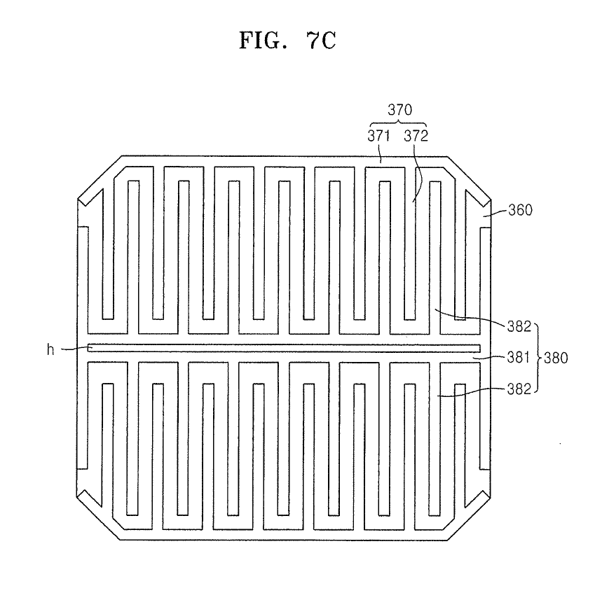

Next, vias (e.g., via holes) 365 are formed in the insulation layer 360 to partially expose the base layer 350 and the emitter layer 340 (refer to FIG. 7B). Although not shown, the via holes 365 may be formed by forming an etching mask (not shown) on the insulation layer 360 and etching a portion of the insulation layer 360 exposed by the etching mask.

The base layer 350 may be partially exposed via (through) some of the plurality of via holes 365, and the emitter layers 340 may be partially exposed via (through) the remaining via holes 365. Some of the via holes 365 are for electric connection between the emitter layers 340 and first metal electrodes 370, whereas the remaining vial holes 365 are for electric connection between the base layer 350 and second metal electrodes 380.

Referring to FIGS. 7A through 7C, the first and second metal electrodes 370 and 380 are formed.

The first metal electrodes 370 are formed at two opposite ends of the rear surface of the semiconductor substrate 310. At least a portion of the first metal electrodes 370 contacts the doped emitter layers 340. The first metal electrodes 370 each includes a first bus bar 371 and first finger electrodes 372 that are formed to extend from (e.g., in a direction perpendicular to) the first bus bar 371.

The second metal electrode 380 is formed at the center of the rear surface of the semiconductor substrate 310. For example, the second metal electrode 380 includes a second bus bar 381 arranged across the center of the semiconductor substrate 310 and second finger electrodes 382 that are formed at two opposite sides around the second bus bar 381 and extend toward the first metal electrodes 370. For example, the second finger electrodes 382 extend in directions substantially perpendicular to the second bus bar 381. The second finger electrodes 382 may be formed to be interdigitated with the first finger electrodes 372 and collect carriers.

The first and second metal electrodes 370 and 380 may be formed by screen-printing a pattern formed of a conductive paste containing silver (Ag), gold (Au), copper (Cu), aluminum (Al), or nickel (Ni), and thermally baking the pattern.

According to another embodiment of the present invention, the first and second metal electrodes 370 and 380 may be formed by plating. After forming seed layers contacting the emitter layer 340 and the base layer 350 through (via) the vias (e.g., via holes) 365, a metal may be plated on the seed layers.

When the second metal electrode 380 is formed, an opening (e.g., hole) h at a center of the second bus bar 381 in a lengthwise direction (refer to FIGS. 7A and 7C) is formed in one embodiment of the present invention. For example, in one embodiment, during formation of the second metal electrode 380, a paste is applied or a metal is plated at regions other than a region corresponding to the opening h so that no metal is formed at the center of the second bus bar 381. A line C-C across the opening h formed at the center of the second bus bar 381 becomes a dicing line. That is, the dicing line can be the opening (e.g., a hole) h in the second metal electrode 380, but the present invention is not limited thereto. However, in another embodiment of the present invention, the dicing line does not have to be an opening or a hole, and can be just an indication on where the second metal electrode 380 should be diced (i.e., at the base portion 350), and no opening or hole is actually formed in the second electrode (e.g., no hole is formed in the second bus bar 381 of the second metal electrode 380).

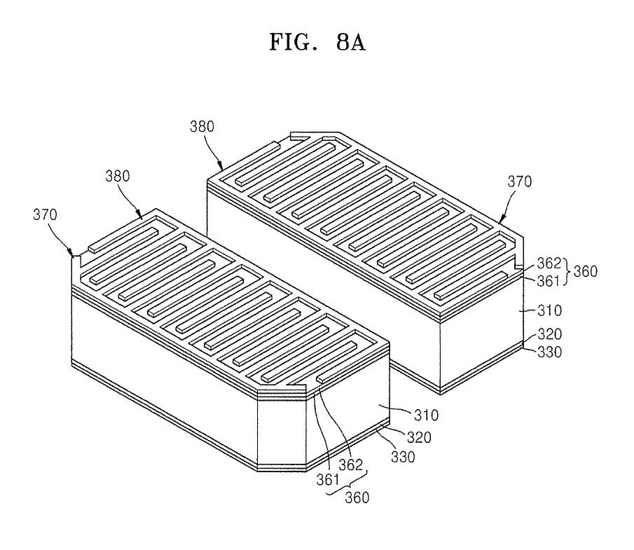

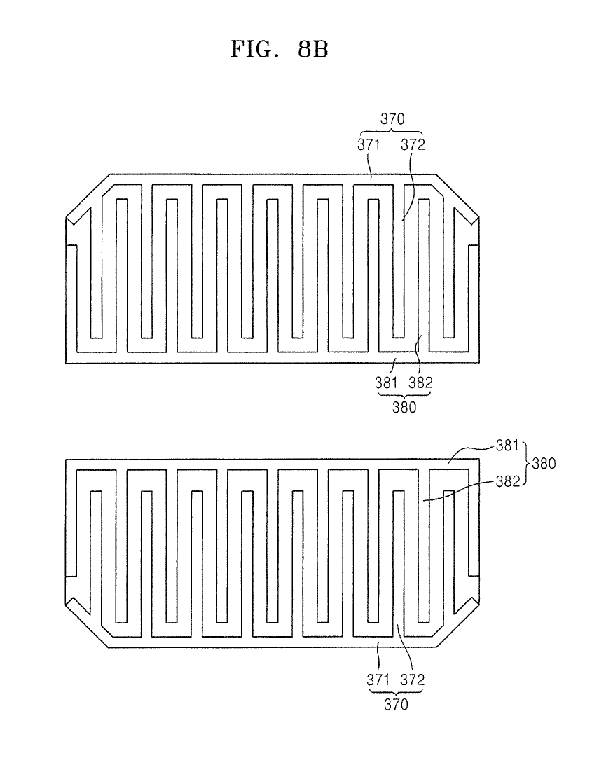

Referring to FIGS. 8A and 8B, two photovoltaic devices may be formed by dicing the semiconductor substrate 310 along the dicing line (e.g., into two separate semiconductor substrate portions). The semiconductor substrate 310 may be diced by using laser scribing. Alternatively, the semiconductor substrate 310 may be diced by using wire sawing. In one embodiment of the present invention, since the dicing is performed with respect to (or at) a base portion of a photovoltaic device and away from an emitter region, possible power loss in fabrication of a photovoltaic device may be reduced or minimized. A detailed description thereof will be given below.

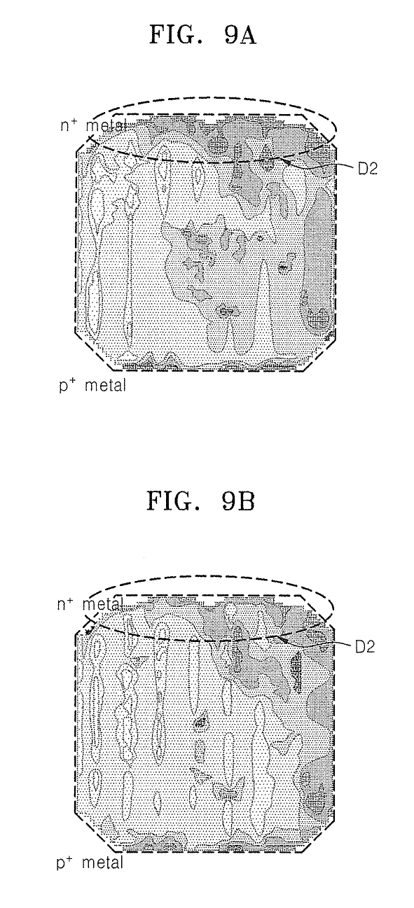

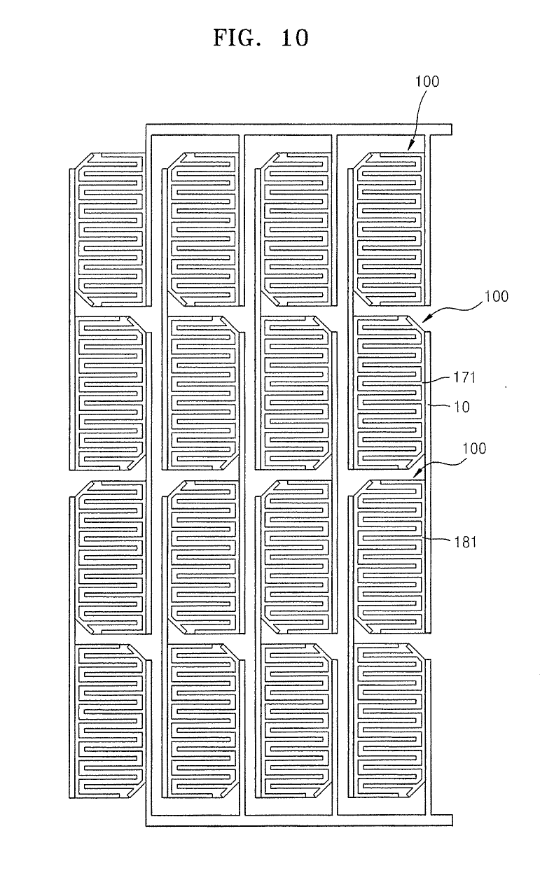

FIGS. 9A and 9B show results of measuring quantum efficiencies (QEs) of comparable back contact photovoltaic devices using a laser beam induced current (LBIC) method.

Referring to FIGS. 9A and 9B, base regions of a base portion are indicated as dark regions D1 and D2. The dark base regions indicate a significantly low current in the corresponding regions. In other words, the base regions make little contribution to efficiency of a photovoltaic device.

Since a base region of the base portion is moved to the center of a semiconductor substrate (wafer) and used as a dicing region according to an embodiment of the present invention, losses due to damaged regions formed during a dicing operation may be reduced or minimized.

As described above, as compared to finger electrodes of a photovoltaic device in a comparable device, first and second metal electrodes 170 and 180 of a photovoltaic device according to an embodiment of the present invention may have finger electrodes 172 and 182 with relatively small lengths, and thus power loss may be reduced. Furthermore, since thicknesses of the metal electrodes 170 and 180 may be reduced, cost for forming the first and second metal electrodes 170 and 180 may be reduced, and bowing of the semiconductor substrate 110 may be reduced or prevented.

And, according to fabricating method of the present invention, a plurality of photovoltaic devices may be produced and the number of processes may be reduced or minimized. For example, two photovoltaic devices may be fabricated by one process cycle (1 cycle) explained according to FIGS. 3A through 8B. Therefore, high efficiency photovoltaic devices may be produced with reduced or minimized cost and time.

Also, according to embodiments of the present invention, a photovoltaic device is formed by dicing one semiconductor wafer in half, and thus a voltage may be approximately doubled and a current may be reduced from the one wafer. Therefore, loss associated with current may be further reduced.

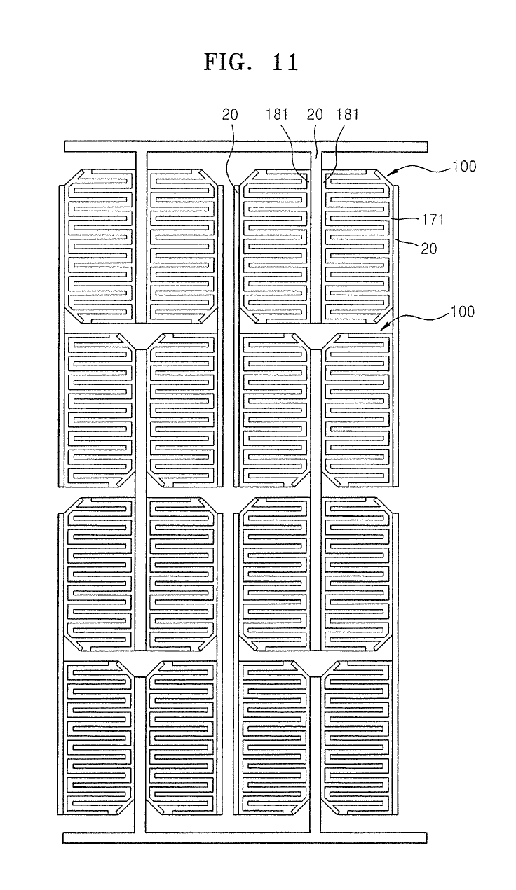

FIGS. 10 through 12 show embodiments of electrically connecting photovoltaic devices according to other embodiments of the present invention.

Referring to FIGS. 10 through 12, modules may be manufactured by electrically interconnecting a plurality of photovoltaic devices by using combinations of serial connections and parallel connections by using ribbons.

Referring to FIG. 10, a single module may be formed by using serial connections by interconnecting the first bus bar 171 arranged at a first end of one of the photovoltaic devices 100 and the second bus bar 181 arranged at a second end of another one of the photovoltaic devices 100 by using a ribbon 10 and interconnecting columns of the photovoltaic devices 100 in parallel.

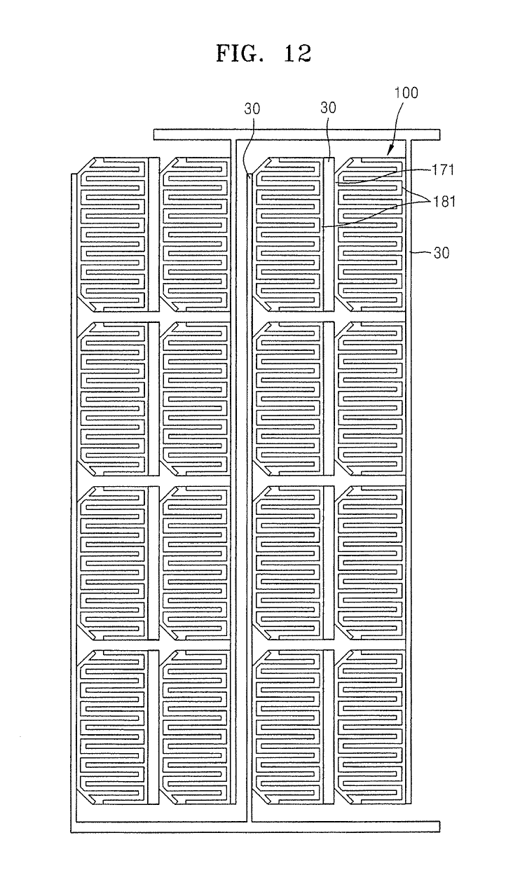

Referring to FIG. 11, a single module may be formed by using a parallel connection by interconnecting the second bus bar 181 arranged at a first end of one of the photovoltaic devices 100 and the second bus bar 181 arranged at a first end of another one of the photovoltaic devices 100 by using a ribbon 20 and interconnecting the photovoltaic devices 100 in series.

Similarly, referring to FIG. 12, a single module may be formed by interconnecting the second bus bar 181 of one of the photovoltaic devices 100 and the first bus bar 171 of another one of the photovoltaic devices 100 by using a ribbon 30 and interconnecting the photovoltaic devices 100 in series and also to interconnect groups of the serially connected photovoltaic devices 100 in parallel.

Other than the embodiments described above, a plurality of photovoltaic devices may be connected to each other in series and/or in parallel through (via) any of various suitable combinations and arrangements.

In view of the foregoing, an embodiment of the present invention provides a method of fabricating a photovoltaic device. Here, the method includes providing a semiconductor substrate (e.g., a semiconductor wafer). Then, a base portion and an emitter portion are formed on a surface of the semiconductor substrate. An insulation layer is formed on the base portion and the emitter portion. The insulation layer has a plurality of vias to partially expose the base portion and the emitter portion. A first electrode is formed to contact a region of the emitter portion through at least one of the vias, and a second electrode is formed to contact a region of the base portion through at least another one of the vias. Then, a dicing line is set at the bus electrode portion of the second electrode, and the semiconductor substrate is split into two photovoltaic devices at the base portion along the dicing line. As such, according to an embodiment of the present invention, two photovoltaic devices are formed by dicing the one semiconductor wafer in half, and thus a voltage may be approximately doubled and a current may be reduced due to the two photovoltaic devices that are formed from the one wafer. Therefore, loss of a current may be reduced.

In addition, since the base region of the base portion is used as the dicing region according to the present invention and because the base region makes little contributions to efficiency of a photovoltaic device, the loss due to the diced or damaged base region formed during the above dicing operation does not significantly affect the formed photovoltaic devices.

While this invention has been particularly shown and described with reference to preferred embodiments thereof, it will be understood by those skilled in the art that various changes in form and details may be made therein without departing from the spirit and scope of the invention as defined by the appended claims. The described embodiments should be considered in descriptive sense only and not for purposes of limitation. Therefore, the scope of the invention is defined not by the detailed description of the invention but by the appended claims, and equivalents thereof.

Description of Reference Numerals

| | |
|---|---|
| 110, 310: semiconductor substrates | 120, 320: passivation layers |
| 130, 330: anti-reflection layers | 140, 340: emitter layers (portions) |
| 150, 350: base layers (portions) | 160, 360: insulation layers |
| 161, 361: first insulation layers | 162, 362: second insulation layers |
| 170, 370: first metal electrodes | 171, 371: first bus bars |
| 172, 372: first finger electrodes | 180, 380: second metal electrodes |
| 181, 381: second bus bars | 182, 382: second finger electrodes |

What is claimed is:

1. A method of fabricating a photovoltaic device, the method comprising:
forming a semiconductor substrate to have a first surface and a second surface, the second surface facing oppositely away from the first surface;
forming a base portion and an emitter portion at the first surface;
forming an insulation layer on the base portion and the emitter portion;
forming a plurality of vias in the insulating layer to partially expose the base portion and the emitter portion;
forming a first electrode to contact a region of the emitter portion through at least one of the vias;
forming a second electrode to contact a region of the base portion through at least another one of the vias;
setting a dicing line at the base portion; and
dicing the semiconductor substrate along the dicing line.

2. The method of claim 1, wherein:
the setting of the dicing line comprises setting the dicing line at the base portion and away from the emitter portion; and
the dicing of the semiconductor substrate comprises dicing the semiconductor substrate at a region of the semiconductor substrate away from the emitter portion.

3. The method of claim 1, wherein:
the forming of the first electrode comprises forming the first electrode to comprise a first bus bar and a plurality of first finger electrodes extending from the first bus bar; and
the forming of the second electrode comprises forming the second electrode to comprise a second bus bar arranged to extend across the center of the first surface and a plurality of second finger electrodes extending from the second bus bar and interdigitated with the first finger electrodes.

4. The method of claim 3, wherein the setting of the dicing line at the base portion comprises forming an opening to extend across the center of the second bus bar to become the dicing line.

5. The method of claim 1, wherein the forming of the semiconductor substrate comprises forming the semiconductor substrate from a single semiconductor wafer by trimming at least two corner portions of the semiconductor wafer.

6. The method of claim 5, wherein a plurality of photovoltaic devices are formed from the single semiconductor wafer.

7. The method of claim 6, wherein:
the forming of the first electrode comprises forming the first electrode in each of the photovoltaic devices to comprise a first bus bar and a plurality of first finger electrodes extending from the first bus bar in each of the photovoltaic devices; and
the forming of the second electrode comprises forming the second electrode in each of the photovoltaic devices to comprise a second bus bar and a plurality of second finger electrodes extending from the second bus bar.

8. The method of claim 1, further comprising:
forming at least one of a passivation layer or an anti-reflection layer at the second surface of the semiconductor substrate.

9. The method of claim 1, further comprising
texturing the second surface of the semiconductor substrate.

10. The method of claim 1, wherein each of the base portion and the emitter portion is formed to have a stripe shape.

11. The method of claim 1, wherein each of the base portion and the emitter portion is formed as a plurality of discrete regions.

12. The method of claim 11, wherein each of the discrete regions has a dot, elliptical, circular, or polygonal shape.

13. The method of claim 1, wherein the second surface is formed as a front surface configured to face a light source, and the first surface is formed as a rear surface configured to face away from the light source.

14. A photovoltaic device, comprising:
a semiconductor substrate having a first surface and a second surface, the second surface facing oppositely away from the first surface;
a base portion and an emitter portion at the first surface;
an insulation layer on the base portion and the emitter portion, the insulation layer having a plurality of vias;
a first electrode contacting a region of the emitter portion through at least one of the vias; and
a second electrode contacting a region of the base portion through at least another one of the vias,
wherein the second electrode is a diced electrode; and
wherein the semiconductor substrate has only two trimmed corner portions at the emitter portion.

15. The photovoltaic device of claim 14, wherein the semiconductor substrate is formed from a semiconductor wafer and is about half (½) the size of the semiconductor wafer.

16. The photovoltaic device of claim 15, wherein a portion of the second electrode extends across the center of the semiconductor wafer.

17. The photovoltaic device of claim 14, wherein:
the first electrode comprises a first bus bar extending along a first edge of the semiconductor substrate between the two trimmed corner portions, and a plurality of first finger electrodes extending from the first bus bar; and
the second electrode comprises a second bus bar extending along a second edge opposite to the first edge, and a plurality of second finger electrodes extending from the second bus bar and interdigitated with the first finger electrodes.

18. The photovoltaic device of claim 14, further comprising:
at least one of a passivation layer or an anti-reflection layer at the second surface of the semiconductor substrate.

19. The photovoltaic device of claim 14, wherein each of the base portion and the emitter portion is formed to have a stripe shape.

20. The photovoltaic device of claim 14, wherein each of the base portion and the emitter portion is formed as a plurality of discrete regions.

21. The photovoltaic device of claim 14, wherein the insulation layer comprises a first layer and a second layer differing in material from the first layer.
